(19) United States
(12) Patent Application Publication
(10) Pub. No.: US 2017/0040568 A1
(43) Pub. Date: Feb. 9, 2017

(54) OLED DISPLAY MOTHERBOARD, PACKAGING METHOD THEREOF AND PACKAGING SYSTEM

(71) Applicants: BOE TECHNOLOGY GROUP CO., LTD., Beijing (CN); ORDOS YUANSHENG OPTOELECTRONICS CO., LTD., Ordos, Inner Mongolia (CN)

(72) Inventors: Xuefei BAI, Beijing (CN); Fuyi CUI, Beijing (CN); Jiuxia YANG, Beijing (CN); Fashun LI, Beijing (CN); Shixin RUAN, Beijing (CN); Ang XIAO, Beijing (CN)

(73) Assignees: Boe Technology Group Co., Ltd., Beijing (CN); Ordos Yuansheng Optoelectronics Co., Ltd., Ordos, Inner Mongolia (CN)

(21) Appl. No.: 14/912,252

(22) PCT Filed: Sep. 16, 2015
(86) PCT No.: PCT/CN2015/089760

§ 371 Date: Feb. 16, 2016

(30) Foreign Application Priority Data
Mar. 6, 2015 (CN) 201510100269.1

(51) Int. Cl. H01L 51/52; H01L 21/67; H01L 51/00; H01L 51/56

(52) U.S. Cl. CPC H01L 51/5246; H01L 51/56; H01L 21/67259; H01L 21/67103; H01L 21/67092; H01L 51/0024

(57) ABSTRACT

The present invention provides an OLED display motherboard, a packaging method thereof and a packaging system, belongs to the field of organic light-emitting display technology, and can solve the problem of poor sealing performance in the existing OLED display motherboard. The OLED display motherboard of the present invention comprises a package cover plate and an OLED substrate, which are assembled with each other in an aligned manner, a sealant is provided between the package cover plate and the OLED substrate, and the sealant is disposed in a peripheral region of the OLED display motherboard, and includes a hot melt adhesive.

### FIELD OF THE INVENTION

The present invention belongs to the field of organic light-emitting display technology, and particularly relates to an OLED display motherboard, a packaging method thereof and a packaging system.

### BACKGROUND OF THE INVENTION

An organic light-emitting diode (OLED) display device, as a new flat panel display device, has drawn more and more attention, and becomes a next-generation display technology that might replace liquid crystal display, due to its characteristics such as active light emission, high luminance, wide viewing angle, quick response, low power consumption, flexibility, and the like.

In an existing OLED device, there is an organic layer material that is extremely sensitive to water vapor and oxygen, and thus the service life of the OLED device is greatly reduced. In order to solve this problem, generally in the prior art, the organic layer material of the OLED device is isolated from the outside with various materials, so that the tightness meets the following criteria: the amount of water vapor is smaller than 10⁻⁶g/m² per day, and the amount of oxygen is smaller than 10⁻³cm³/m² per day. In the prior art, the main sealing method includes: placing an OLED substrate including a plurality of display regions on an operating platform of a bonding machine; coating a UV adhesive on the peripheral region of a package cover plate to be bonded with the OLED substrate; coating frit on the package regions around the display regions on the OLED substrate; then, vacuumizing an environment, in which the bonding machine is located, bonding the package cover plate with the OLED substrate to form an OLED display motherboard; after the bonding, introducing nitrogen into the environment to release the vacuum state of the environment, and then placing the bonded package cover plate and OLED substrate in the atmospheric environment. At this time, the peripheral region of the package cover plate is irradiated with a UV lamp so that the UV adhesive in that region is cured. Subsequently, a laser is emitted towards positions with the frit provided, so that the OLED substrate of the OLED panel corresponding to each display region and the package substrate are bonded, and thereafter, cutting the OLED display motherboard according to the respective package regions to form the OLED panels.

Inventor(s) found that at least the following problem exists in the prior art: before irradiating the peripheral region of the package cover plate with a UV lamp, since there is a pressure difference between the UV adhesive in the cell and the UV adhesive in the atmospheric environment, the UV adhesive in that region is likely to be “penetrated” to allow the gases to enter into the cell from the outside, and at this time, the frit has not been cured yet, so the OLED device may be contaminated.

### SUMMARY OF THE INVENTION

In view of the above problem in sealing of the existing OLED display motherboard, the present invention provides an OLED display motherboard with good sealing performance, a packaging method thereof and a packaging system,

The technical solution adopted to solve the technical problem of the present invention is an OLED display motherboard, comprising a package cover plate and an OLED substrate assembled with each other in an aligned manner, a sealant is provided between the package cover plate and the OLED substrate, and the sealant is disposed in a peripheral region of the OLED display motherboard, and includes a hot melt adhesive.

Preferably, the hot melt adhesive is any one of EVA hot melt adhesive, polyester-based hot melt adhesive, and hot melt sealing adhesive.

Preferably, middle region of the OLED display motherboard is provided with a plurality of display regions and package regions around the display regions, and a frame-sealant is provided at positions, corresponding to the package regions, between the package cover plate and the OLED substrate.

Further preferably, the material of the frame-sealant includes frit.

The technical solution adopted to solve the technical problem of the present invention is a packaging system comprising a sealant coating device which comprises: a first bearing platform, configured for bearing a package cover plate; and a coating mechanism, configured for coating a sealant in a peripheral region of the package cover plate, and the sealant includes a hot melt adhesive.

Preferably, the coating mechanism comprises a collecting unit, a tray, a plurality of fixing columns provided on the tray and a driver. The collecting unit is configured for collecting positional relationship between the respective fixing columns and reference points on the package cover plate to be subjected to coating. The driver is configured for, based on the positional relationship between the fixing columns and the reference points on the package cover plate to be subjected to coating collected by the collecting unit, adjusting each fixing column in an initial active region corresponding thereto on the tray, and driving each fixing column to coat the hot melt adhesive in the peripheral region of the package cover plate.

Further preferably, the collecting unit comprises a plurality of cameras in one-to-one correspondence with the plurality of fixing columns, and each camera is fixed to one fixing column corresponding thereto.

Further preferably, one end of each fixing column close to the first bearing platform is provided with a heating head, which is configured for preheating at least part of the hot melt adhesive after the hot melt adhesive is coated in the peripheral region of the package cover plate.

Further preferably, the number of the fixing columns is four, and the four fixing columns are disposed at four corners of the tray, respectively.

Preferably, the packaging system further comprises a bonding device which comprises: a second bearing platform configured for bearing an OLED display motherboard; and a heating unit configured for heating the peripheral region of the package cover plate after the OLED display motherboard is formed by assembling the package cover plate and an OLED substrate in an aligned manner.

Further preferably, the heating unit is made of electrical resistance heating strip.

Further preferably, the bonding device further comprises a pressing unit which is configured for pressing the peripheral region of the OLED display motherboard after the OLED display motherboard is formed by assembling the package cover plate and the OLED substrate in an aligned manner.

Further preferably, the pressing unit is made of flexible material.

The technical solution adopted to solve the technical problem of the present invention is a packaging method of an OLED display motherboard, comprising steps of coating a hat melt adhesive in a peripheral region of a package cover plate;
assembling the package cover plate subjected to the above step and an OLED substrate in an aligned manner to form the OLED display motherboard; and heating a peripheral region of the OLED display motherboard to seal the package cover plate and the OLED substrate.

Preferably, the step of coating a hot melt adhesive in the peripheral region of a package cover plate comprises: determining positions of a plurality of reference points in the peripheral region of the package cover plate, determining positional relationship between the plurality of reference points and an area to be coated with the hot melt adhesive, and coating the hot melt adhesive in the peripheral region of the package cover plate.

Preferably, before the step of assembling the package cover plate and the OLED substrate in an aligned manner, the packaging method further comprises: preheating an area where the plurality of reference points are located in the package cover plate with the hot melt adhesive coated in the peripheral region thereof, so as to pre-bond the hot melt adhesive and the package cover plate.

In the packaging method, the number of the plurality of reference points may be four.

In the packaging method, the heating temperature for preheating the area where the plurality of reference points are located may be in a range of 95±5° C.

Preferably, the heating temperature for heating the peripheral region of the OLED display motherboard is in a range of 95±5° C.

Preferably, after the step of heating the peripheral region of the OLED display motherboard, the packaging method further comprises: pressing, by a pressing unit, the peripheral region of the OLED display motherboard.

In the OLED display motherboard according to the embodiment of the present invention, the package cover plate and the OLED substrate are sealed by the hot melt adhesive, so that the OLED display motherboard formed by assembling the both in an aligned manner has better sealing performance.

In the packaging method according to the embodiment of the present invention, the package cover plate and the OLED substrate of the OLED display motherboard are sealed with the hot melt adhesive, and as compared to the UV adhesive, the hot melt adhesive is of low cost, has a simple arrangement process, and is easy to implement, and no curing process is needed for the hot melt adhesive after the package cover plate and the OLED substrate are assembled in an aligned manner, therefore, the cost can be saved and production efficiency can be improved.

The packaging system according to the embodiment of the present invention has a simple structure, and can perfectly seal the package cover plate and the OLED substrate, and thus the OLED display motherboard formed after sealing has better performance.

### BRIEF DESCRIPTION OF THE DRAWINGS

FIG. 1 is a schematic diagram of a package cover plate of an OLED display motherboard in an embodiment of the present invention.

FIG. 2 is a schematic diagram of an OLED substrate of an OLED display motherboard in an embodiment of the present invention.

FIG. 3 is a schematic diagram of a sealant coating device in a packaging system in an embodiment of the present invention.

FIG. 4 is a schematic diagram of a coating mechanism in the sealant coating device shown in FIG. 3.

FIG. 5 is a bonding device in a packaging system in an embodiment of the present invention.

### DETAILED DESCRIPTION OF THE EMBODIMENTS

To enable those skilled in the art to better understand the technical solutions of the present invention, the present invention will be further described in detail below in conjunction with the accompanying drawings and the specific implementations.

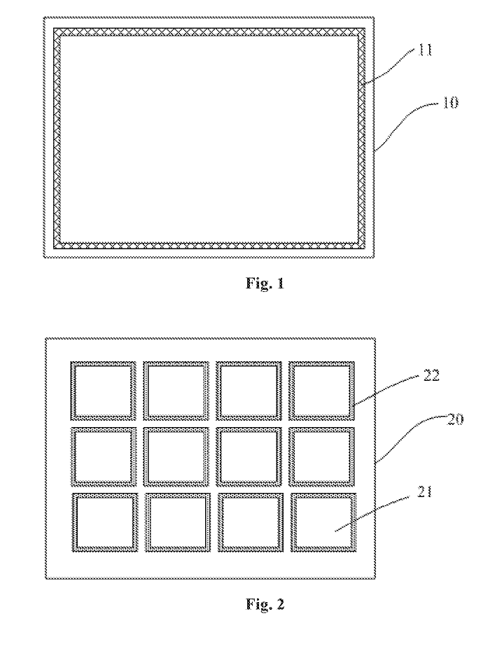

Referring to FIGS. 1 and 2, one embodiment of the present invention provides an OLED display motherboard, which includes a package cover plate 10 and an OLED substrate 20, assembled with each other in an aligned manner. A sealant is provided between the package cover plate 10 and the OLED substrate 20, and the sealant is disposed in the peripheral region of the OLED display motherboard, and includes a hot melt adhesive 11.

In the peripheral region of the OLED display motherboard of this embodiment, since the space between the package cover plate 10 and the OLED substrate 20 is sealed by the hot melt adhesive 11 which itself has a better adhesion property as compared with the UV adhesive, the package cover plate 10 and the OLED substrate 20 can be well sealed, particles and impurities in the external environment can be effectively prevented from entering into the interior of the OLED display motherboard to contaminate the devices inside the OLED display motherboard, and thus the problem of low bonding yield of the OLED display motherboard can be improved.

For example, the hot melt adhesive 11 in this embodiment is any one of EVA (ethylene and vinyl acetate copolymer) hot melt adhesive, polyester-based hot melt adhesive, and hot melt sealing adhesive. Needless to say, the hot melt adhesive 11 in this embodiment is not limited thereto, and may also be other hot melt adhesive similar thereto, which is not elaborated here.

In this embodiment, the middle region of the OLED display motherboard is provided with a plurality of display regions 21 and package regions 22 around the display regions. A frame-sealant is provided at positions, corresponding to the package regions 22, between the package cover plate 10 and the OLED substrate 20. For example, the material of the frame-sealant is frit.

In the OLED display motherboard of this embodiment, the package cover plate 10 and the OLED substrate 20 are sealed by the hot melt adhesive 11, so the OLED display motherboard formed by assembling both in an aligned manner has better sealing performance.

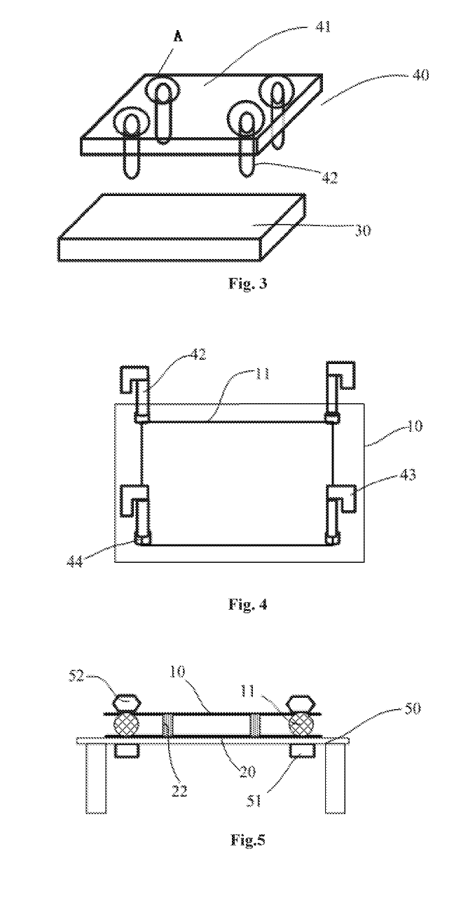

Referring to FIGS. 3 and 4, another embodiment of the present invention provides a packaging system, which includes a sealant coating device. The sealant coating device includes: a first bearing platform 30, configured for bearing the package cover plate and a coating mechanism 40, configured for coating the hot melt adhesive 11 in the peripheral region of the package cover plate 10.

In this embodiment, the sealant coating device included in the packaging system achieves a better tightness when assembling the package cover plate 10 and the OLED substrate 20 in an aligned manner, by coating the hat melt adhesive 11 in the peripheral region of the package cover plate 10.

For example, the coating mechanism 40 of this embodiment includes a collecting unit 43, a tray 41, a plurality of fixing columns 42 provided on the tray 41 and a driver (not shown). The collecting unit 43 is configured for collecting positional relationship between the respective fixing columns 42 and reference points on the package cover plate 10 to be subjected to coating. The driver is configured for, based on the positional relationship between the fixing columns 42 and the reference points on the package cover plate 10 to be subjected to coating collected by the collecting unit 43, adjusting each fixing column 42 in an initial active region (which refers to a region in which the fixing column 42 is allowed to move to adjust the initial position of the fixing column 42 on the tray to an initial position properly corresponding to the reference point, for example, the area A defined by a circle shown in the figure) corresponding thereto on the tray 41 so as to position the fixing column 42 at a suitable initial position, and for driving each fixing column 42 to coat the hot melt adhesive 11 in the peripheral region of the package cover plate 10.

For example, the collecting unit 43 of this embodiment includes a plurality of cameras in one-to-one correspondence with the plurality of fixing columns 42, and each camera is fixed to one fixing column 42 corresponding thereto. One end of each fixing column 42 close to the first bearing platform 30 is provided with a heating head 44, which is configured for heating at least part of the hot melt adhesive 11 after coating the hot melt adhesive 11 in the peripheral region of the package cover plate 10, so as to pre-bond the hot melt adhesive 11 and the peripheral region of the package cover plate 10. For example, the number of the fixing columns 42 is four, the four fixing columns 42 are disposed at four corners of the tray 41, respectively, and accordingly, the number of the cameras corresponding thereto is four. In this case, the coating mechanism 40 has a simple structure and is easy to operate.

As shown in FIG. 5, the packaging system of this embodiment may further include: a bonding device, which includes a second bearing platform 50 and a heating unit 51. The second bearing platform 50 is configured for bearing the OLED display motherboard which is formed by assembling the package cover plate 10 obtained after coating the hot melt adhesive thereon and the OLED substrate 20 in an aligned manner. The heating unit 51 is configured for, after the OLED display motherboard is formed by assembling the package cover plate 10 and the OLED substrate 20 in an aligned manner, heating the peripheral region of the package cover plate 10 to fully bond the package cover plate 10 and the OLED substrate 20, so that an OLED display motherboard with good tightness is obtained.

For example, the heating unit 51 of this embodiment is made of electrical resistance heating strip. Needless to say, the heating. unit 51 of this embodiment is not limited thereto, and may be other device with heating function. There are many existing devices with heating function, which are not elaborated here.

In this embodiment, the bonding device further includes a pressing unit 52, which is configured for, after the OLED display motherboard is formed by assembling the package cover plate 10 and the OLED substrate 20 in an aligned manner, pressing the peripheral region of the OLED display motherboard to fully bond the package cover plate 10 and the OLED substrate 20 and obtain the OLED display motherboard with good tightness. For example, the pressing unit 52 is made of flexible material. The flexible material has soft texture, and will not cause damage to the OLED display motherboard due to large pressure when pressing the peripheral region of the OLED display motherboard.

Another embodiment of the present invention provides a packaging method for packaging an OLED display motherboard, the OLED display motherboard may be the OLED display motherboard described in the above embodiments, and the packaging method may be applied in the packaging device in the above embodiment and includes the following step S01 to step S03.

At step S01, hot melt adhesive 11 is coated in the peripheral region of the package cover plate 10.

This step specifically includes: firstly placing the package cover plate 10 on a first bearing platform 30, determining positions of a plurality of reference points in the peripheral region of the package cover plate 10, determining positional relationship between the plurality of reference points and areas to be coated with the hot melt adhesive 11, and coating the hot melt adhesive 11 in the peripheral region of the package cover plate 10; thereafter, heating a area where the plurality of reference points are located in the package cover plate 10 with the hot melt adhesive 11 coated in the peripheral region thereof in this step, the hot melt adhesive 11 is heated with a temperature in a range of 95±5° C. (i.e., softening point of the hot melt adhesive 11). In this step, preheating the positions of the plurality of reference points allows the hot melt adhesive 11 and the positions of the plurality of reference points of the package cover plate 10 to be pre-bonded, so that gap between the package cover plate 10 and the hot melt adhesive 11 is avoided. For example, the number of the reference points is four.

At step S02, the package cover plate 10 subjected to the above step and an OLED substrate 20 are assembled in an aligned manner in a vacuum environment.

In this step, the OLED substrate 20 is disposed on a second bearing platform 50 first, the package cover plate 10 subjected to the coating in step S01 is mechanically aligned with the OLED substrate 20 by a mechanical arm, and then precise alignment is performed. The alignment method is consistent with the existing method of aligning the OLED substrate 20 and the package cover plate 10, and thus is not elaborated here.

At step S03, peripheral region of the OLED display motherboard is heated in a vacuum environment to seal the package cover plate 10 and the OLED substrate 20.

In this step, the peripheral region of the OLED display motherboard is heated, that is, the heating is performed at one side of the OLED substrate 20 away from the package cover plate 10, and the hot melt adhesive 11 is heated with a temperature in a range of 95±5° C. (i.e., softening point of the hot melt adhesive 11) to fully bond the package cover plate 10 and the OLED substrate 20. Particularly, in order to better bond the package cover plate 10 and the OLED substrate 20, for example, nitrogen is introduced into the environment where the OLED display motherboard is located, after the peripheral region of the OLED display motherboard is heated. In this case, the packaging method further includes: pressing the peripheral region of the OLED display motherboard by a pressing unit, that is, the pressing is performed by the pressing unit at the side of the package cover plate 10 away from the OLED substrate 20, so that the package cover plate 10 and the OLED substrate 20 are bonded together more fully. Here, the pressing unit is made of flexible material, so as to avoid damage to the package cover plate in the pressing process.

In the packaging method of this embodiment, the package cover plate 10 and the OLED substrate 20 of the OLED display motherboard are sealed with the hot melt adhesive 11, and compared to the UV adhesive, the hot melt adhesive 11 is of low cost, has a simple coating process, and is easy to implement, and no curing process is needed for the hot melt adhesive 11 after the package cover plate 10 and the OLED substrate 20 are assembled in an aligned manner, therefore, the cost can be saved and production efficiency can be improved.

It can be understood that, the above implementations are merely exemplary implementations configured for explaining the principle of the present invention, but the present invention is not limited thereto. For those skilled in the art, various modifications and improvements may be made without departing from the spirit and essence of the present invention, and these modifications and improvements are also deemed as falling within the protection scope of the present invention.

1. An OLED display motherboard, comprising a package cover plate and an OLED substrate assembled with each other in an aligned manner, wherein, a sealant is provided between the package cover plate and the OLED substrate, and the sealant is disposed in a peripheral region of the OLED display motherboard, and includes a hot melt adhesive.

2. The OLED display motherboard according to claim 1, wherein, the hot melt adhesive is any one of EVA hot melt adhesive, polyester-based hot melt adhesive, and hot melt sealing adhesive.

3. The OLED display motherboard according to claim 1, wherein, middle region of the OLED display motherboard is provided with a plurality of display regions and package regions around the display regions, and a frame-sealant is provided at positions, corresponding to the package regions, between the package cover plate and the OLED substrate.

4. The OLED display motherboard according to claim 3, wherein, the material of the frame-sealant includes frit.

5. A packaging system, comprising a sealant coating device which comprises:
a first bearing platform, configured for bearing a package cover plate; and
a coating mechanism, configured for coating a sealant in a peripheral region of the package cover plate, the sealant including a hot melt adhesive.

6. The packaging system according to claim 5, wherein, the coating mechanism comprises a collecting unit, a tray, a plurality of fixing columns provided on the tray and a driver, and wherein
the collecting unit is configured for collecting positional relationship between the respective fixing columns and reference points on the package cover plate to be subjected to coating; and
the driver is configured for, based on the positional relationship between the fixing columns and the reference points on the package cover plate to be subjected to coating collected by the collecting unit, adjusting each fixing column in an initial active region corresponding thereto on the tray, and driving each fixing column to coat the hot melt adhesive in the peripheral region of the package cover plate.

7. The packaging system according to claim 6, wherein, the collecting unit comprises a plurality of cameras in one-to-one correspondence with the plurality of fixing columns, and each camera is fixed to one fixing column corresponding thereto.

8. The packaging system according to claim 6, wherein, one end of each fixing column close to the first bearing platform is provided with a heating head, which is configured for preheating at least part of the hot melt adhesive after the hot melt adhesive is coated in the peripheral region of the package cover plate.

9. The packaging system according to claim 6, wherein, the number of the fixing columns is four, and the four fixing columns are disposed at four corners of the tray, respectively.

10. The packaging system according to claim 5, further comprising a bonding device which comprises:
a second bearing platform configured for bearing an OLED display motherboard; and
a heating unit configured for heating the peripheral region of the package cover plate after the OLED display motherboard is formed by assembling the package cover plate and an OLED substrate in an aligned manner.

11. The packaging system according to claim 10, wherein, the heating unit is made of electrical resistance heating strip.

12. The packaging system according to claim 10, wherein, the bonding device further comprises a pressing unit which is configured for pressing the peripheral region of the OLED display motherboard after the OLED display motherboard is formed by assembling the package cover plate and the OLED substrate in an aligned manner.

13. The packaging system according to claim 12, wherein, the pressing unit is made of flexible material.

14. A packaging method of an OLED display motherboard, comprising steps of:
coating a hot melt adhesive in a peripheral region of a package cover plate;
assembling the package cover plate subjected to the above step and an OLED substrate in an aligned manner to form the OLED display motherboard; and
heating a peripheral region of the OLED display motherboard to seal the package cover plate and the OLED substrate.

15. The packaging method of an OLED display motherboard according to claim 14, wherein, the step of coating a hot melt adhesive in the peripheral region of a package cover plate comprises:
determining positions of a plurality of reference points in the peripheral region of the package cover plate, determining positional relationship between the plurality of reference points and an area to be coated with the hot melt adhesive, and coating the hot melt adhesive in the peripheral region of the package cover plate.

16. The packaging method of an OLED display motherboard according to claim 15, wherein, before the step of assembling the package cover plate and the OLED substrate in an aligned manner, the packaging method further comprises:
preheating an area where the plurality of reference points are located in the package cover plate with the hot melt adhesive coated in the peripheral region thereof, so as to pre-bond the hot melt adhesive and the package cover plate.

17. The packaging method of an OLED display motherboard according to claim 16, wherein, the number of the plurality of reference points is four.

18. The packaging method of an OLED display motherboard according to claim 16, wherein, heating temperature for preheating the area where the plurality of reference points are located is in a range of 95±5° C.

19. The packaging method of an OLED display motherboard according to claim 14, wherein, heating temperature for heating the peripheral region of the OLED display motherboard is in a range of 95±5° C.

20. The packaging method of an OLED display motherboard according to claim 14, wherein, after the step of heating the peripheral region of the OLED display motherboard, the packaging method further comprises: pressing, by a pressing unit, the peripheral region of the OLED display motherboard.
